(19) United States
(12) Patent Application Publication
(10) Pub. No.: US 2026/0079187 A1
(43) Pub. Date: Mar. 19, 2026

(54) HIGH FREQUENCY DETECTOR

(71) Applicant: Infineon Technologies AG, Neubiberg (DE)

(72) Inventor: Marco BUCCI, Graz (AT)

(21) Appl. No.: 18/886,270

(22) Filed: Sep. 16, 2024

(51) Int. Cl. G01R 19/165; H03F 3/00; H03F 3/195; H03K 3/57; H04B 1/16; H04B 1/18

(52) U.S. Cl. CPC G01R 19/1659; H03F 3/005; H04B 1/1615; H03F 3/195; H03K 3/57; H04B 1/18

(57) ABSTRACT

Devices, systems, and methods providing for improved detection of a high frequency component in an input signal are described. A detector includes a detector stage configured to receive an input signal and generate a detection signal that represents the input signal. The detector also includes an amplifier stage that configured to receive the detection signal from the detector stage and amplify the detection signal to generate an output signal that indicates whether the input signal includes a high frequency component. In some examples, the detector stage includes a switched cap detector and the amplifier stage includes a first switched cap amplifier and a second switched cap amplifier. In some examples, the switched cap detector and the first switched cap amplifier are operated responsive to a first clock signal, and the second switched cap amplifier is operated responsive to a second clock signal different than the first clock signal.

### TECHNICAL FIELD OF THE INVENTION

This invention relates generally to communications systems, and more specifically to techniques for detecting an incoming high frequency component in an input signal.

### BACKGROUND

In some applications, a receiver of a traditional communications system is coupled to receive an input signal from a wireless antenna or a wired communications channel. For example, the receiver may demodulate, sample, and/or otherwise process the input signal to extract data from the input signal. In some examples, in order to conserve energy, a receiver of a communications system may be configured to enter a sleep mode when no input signal is being transmitted.

Traditional communications systems may include detection circuitry to detect when an input signal is being transmitted over a wired or wireless communications channel so that receiver circuitry can be awakened to receive the input signal. Such traditional detection circuitry is configured to first amplify and/or rectify the input signal, and then compare the amplified input signal to a reference voltage to identify the presence of a high frequency component. In some examples, such traditional detection circuitry may consume a significant amount of power and/or may use components that are relatively expensive and/or difficult to implement to detect the presence of a high frequency component in an input signal.

### SUMMARY

In some aspects, a detector includes a detector stage configured to receive an input signal and generate a detection signal that represents the input signal; and an amplifier stage that configured to receive the detection signal from the detector stage and amplify the detection signal to generate an output signal that indicates whether the input signal includes a high frequency component.

In some aspects, a method includes operating a detector stage to receive an input signal and generate a detection signal that represents the input signal. The method further includes operating an amplifier stage following the detector stage to receive the detection signal from the detector stage and amplify the detection signal to generate an output signal that indicates whether the input signal includes a high frequency component.

In some aspects, a system includes a receiver configured to receive an input signal and extract data from the input signal. The system further includes a detector that includes a detector stage configured to receive an input signal and generate a detection signal that represents the input signal and an amplifier stage configured to receive the detection signal from the detector stage and amplify the detection signal to generate an output signal that indicates whether the input signal includes a high frequency component. The system further includes a wakeup circuit configured to wake the receiver in response to the output signal of the detector.

### BRIEF DESCRIPTION OF THE DRAWINGS

FIG. 1 is a block diagram depicting one example of a system that includes a receiver and a detector according to some embodiments.

FIG. 2 is a block diagram depicting one example of a detector according to some embodiments.

FIG. 3 is a timing diagram showing respective signals associated with operation of a detector according to some embodiments.

FIG. 4 depicts plots showing simulations results of a detector according to some embodiments.

FIG. 5 is a flow diagram that depicts a method of operating a detector according to some embodiments.

### DETAILED DESCRIPTION

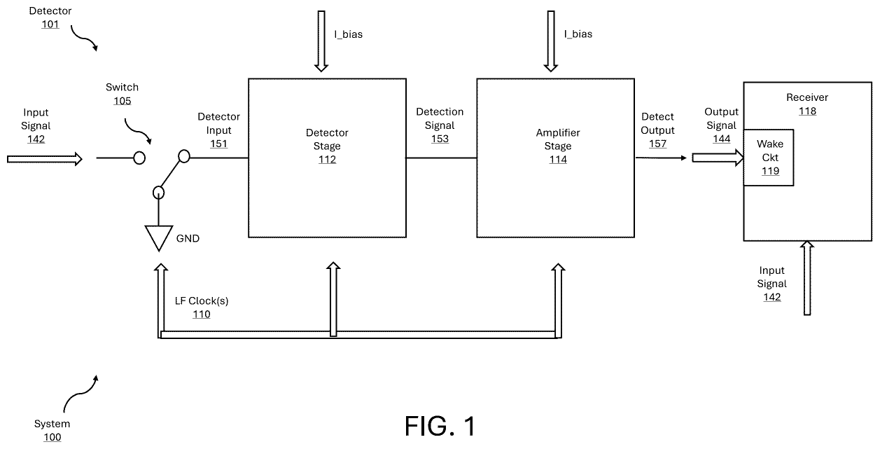

FIG. 1 is a block diagram depicting one example of a system 100 that includes a receiver 118 and a detector 101 according to some embodiments. The detector 101 is configured to be coupled to an input signal 142 that includes a high frequency component when information is being communicated using the input signal 142. The input signal 142 may be received from a signal source such as a wireless antenna or a wired communications channel. The detector 101 is configured to be coupled to the input signal 142 to generate an output signal 144 that indicates whether the input signal 142 includes a high frequency component. As shown in FIG. 1 the output signal 144 may be output to wake circuitry 119 to awaken demodulation, amplification, sampling, or other circuitry of a receiver 118 to receive the input signal 142. For example, in response to the output signal 144 of the detector 201, the wake circuitry 119 may couple a power source to one or more components of the receiver 118 so that they operate to receive the input signal 142 and extract information such as data from the input signal 142.

In some examples, traditional circuits configured detect a high frequency component in an input signal first amplify and rectify the input signal before comparing the input signal to a reference voltage. In some examples, traditional detector circuits may consume a significant amount of energy to detect a high frequency component in the input signal because the input amplifier must remain on (i.e., powered) to amplify and/or rectify the input signal before it is compared to detect the high frequency component. Rectification circuitry may also consume a significant amount of power to operate and/or may be expensive/complex to implement. In some examples, generating a stable reference voltage suitable for comparison to an amplified input signal may use relatively costly and/or complex to implement components such as a band gap reference and associated circuitry. In some examples, operating a stable reference voltage for comparison may also consume significant energy.

In the example of FIG. 1, the detector 101 is uniquely configured to detect the presence of a high frequency component in an input signal 142 with reduced power consumption, cost, and/or complexity in comparison to traditional detector circuits. As shown in FIG. 1, the detector 101 includes a detector stage 112 and an amplifier stage 114 that follows the detector stage 112. As shown in FIG. 1, the detector stage 112 is configured to receive the input signal 142 at the detector input 151 before the input signal 142 is amplified and/or rectified. As shown in FIG. 1, the detector 101 may further include at least one switch 105 that is coupled between a detector input 151 of the detector stage 112 and the input signal 142 as shown.

In various embodiments described in further detail below, the detector stage 112 and the amplifier stage 114 are alternatingly operable in a biasing phase and a sampling phase to detect a high frequency component in the input signal 144. In some examples, in the biasing phase, the at least one switch 105 couples the detector input 151 of the detector stage 112 to a ground reference, and a bias current I_bias is supplied to the detector stage 112 and/or the amplifier stage 114. In some examples, in the sampling phase, the at least one switch 105 couples the detector input 151 to the input signal 142 to sample the input signal 142, and the detector stage 112 outputs a detection signal 153 that represents the input signal 142, specifically whether the input signal 142 includes a high frequency component. In some examples, the detection signal 153 is amplified by the amplifier stage 114 as a detect output signal 157. In some examples, the detect output signal 157 may be used as an output signal 144 of the detector 101 to indicate whether the input signal 142 includes a high frequency component. In other examples, the detect output signal 157 is further processed to generate the output signal 144.

In some examples, each of the one or more switch(s) 105, the detector stage 112, and the amplifier stage 114 are operated intermittently using one or more relatively low frequency clock(s) 110 as shown in FIG. 1, which may conserve a significant amount of energy. In some examples, the low frequency clock(s) 110 may have a much lower frequency F_{clk} than a carrier frequency F_{c} of the input signal 142. For example, the carrier frequency F_{c} of the input signal 142 may be greater than 10 megahertz (MHz, and the frequency F_{clk} of the low frequency clock(s) 110 may be less then 100 kilohertz (kHz). In some examples, the switch(s) 105, components of the detector stage 112, and amplifier stage 114 may each operate using one or more different clock signals that are also relatively low frequency clock signals.

In some examples, the detector stage 112 and the amplifier stage 114 each use a bias signal I_bias as shown in FIG. 1 to generate the detection signal 153 and amplify the detection signal 153 as the detect output signal 157. In some examples, the components of the detector stage 112 and the amplifier stage 114 use the same bias current I_bias. In some examples, the bias current I_bias is around 100 nanoamperes (nA), for example between around 50 and around 150 nA. In some examples, the detector 101 includes at least one beta multiplier circuit (not shown) to generate the bias current(s) I_bias.

In some examples, the detector stage 112 includes a switched cap detector, and the amplifier stage 114 includes a first switched cap amplifier and a second switched cap amplifier. In some examples, the switched cap detector and the first switched cap amplifier are operated based on the same clock signal, and the switched cap amplifier is operated based on a different clock than the switched cap detector and the first switched cap amplifier.

In some examples, the detector 101 depicted in FIG. 1 does not perform amplification of the input signal 142 itself. Instead, the detector 101 makes use of non-linear behavior of an input transistor of the switched cap detector circuit 122, i.e., that an average current of the input transistor may increase when an input signal 142 with a high frequency component is applied to the input transistor gate. In order to detect such an increase, the detector 101 is configured to cyclically bias the input transistor in absence of the input signal 142 in the biasing phase, and then connect the input transistor to the input signal 142 in the detection phase. The detector 101 generates the detection signal 153, which represents a variation in the average current of the input transistor between the biasing phase and the detection phase, which is amplified by the amplifier stage 114 as the detect output signal 157.

In some examples, detector 101 depicted in FIG. 1 may offer significant advantages over traditional circuits used to detect a high frequency component in an input signal. For example, detector stage 112 may be uniquely configured to detect the input signal 142 and generate a detection signal 153 that represents the input signal 142 (i.e., represents the previously mentioned shift between the cyclical detection phase and biasing phase when a high frequency component is present) without the input signal 142 first being amplified and/or rectified like with traditional detectors, which may enable detector 101 to consume less energy in comparison to traditional detector circuits. In other examples, the detector 101 is operable to generate and amplify the detection signal 153 using a bias current I_bias, which may be less complicated and/or costly to implement in comparison to traditional detectors that utilize a stable reference voltage, for example from a bandgap reference device, to detect a high frequency component in an input signal.

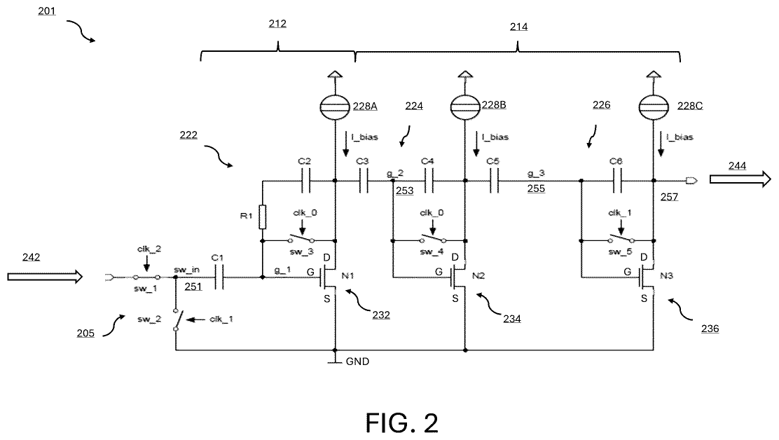

FIG. 2 is a block diagram depicting one example of a detector 201 according to some embodiments. As shown in FIG. 2, the detector includes a detector stage 212 configured to receive an input signal 242 at a detector input sw_in 251, and generate a detection signal 253 at the node labeled g_2. As shown in FIG. 2, the detector 201 also includes an amplifier stage 214 that receives the detection signal 253 from the detector stage 212 and amplifies the detection signal 253 to generate an output signal 244 that indicates whether the input signal 242 includes a high frequency component.

As shown in FIG. 2, the detector 201 includes detector input sw_in 251 and a switch sw_1 coupled between the detector input sw_in 251 and the input signal 242, and a switch sw_2 coupled between the detector input sw_in 251 and a ground reference GND. The switches 205, including switch sw_1 and switch sw_2, are configured to be driven by complementary clock signals to alternate between a detection phase in which the detector input (sw_in) is coupled to the input signal 242, and a biasing phase in which the detector input sw_in is coupled to the ground reference GND.

In the example of FIG. 2, the detector stage 212 includes a switched cap detector 222 that is configured to receive an input signal 242 and generate a detection signal 253 that represents the input signal 242 (e.g., a high frequency component in the input signal 242). In the example of FIG. 2, the switched cap detector 222 includes a first switch sw_3 coupled between a gate terminal (the node labeled g_1) and a drain terminal of a first transistor N1 232. As shown in FIG. 2, a gate terminal of the first transistor N1 232 is coupled to the input signal 242 via a capacitor C1 coupled between the detector input 151 and the gate terminal of the first transistor 232. As shown in FIG. 2, the switched cap detector 222 includes a resistor R1 and a capacitor C2 coupled in series between the gate terminal and the drain terminal of the first transistor N1 232. As shown in FIG. 2, the detector stage 212 further includes a current source 228A coupled to supply a bias current I_bias to the detector stage 212, for example to a drain terminal of the first transistor N1 232.

In the example of FIG. 2, the first transistor 232 may be described as an input transistor of the detector stage 212 in that the input signal 242 is coupled to the gate of the first transistor 232 (at the node labeled g_1) in a detection phase. In some examples, the detector stage 212 utilizes a non-linear characteristic of the first transistor 232 to generate a detection signal 253 responsive to a change in a drain source voltage V_{DS} of the first transistor 232 that is caused by a change in average current I_{DS} through the first transistor 232 when the input signal 242 includes a high frequency component. A high frequency component becoming present (i.e., due to a transmitter commencing transmission) in the input signal 242 may cause the current through the first transistor 232 to increase, which causes the drain source voltage V_{DS} of the first transistor 232 to decrease as a pulse in the detection signal 253.

In the example of FIG. 2, the amplifier stage 214 includes at least one switched cap amplifier 224, 226 configured to receive the detection signal 253 from the switched cap detector 222 and amplify the detection signal 253 to generate an output signal 244 to indicate whether the input signal 242 includes a high frequency component. In the example of FIG. 2, the amplifier stage 214 includes two switched cap amplifiers, a first switched cap amplifier 224 followed by a second switched cap amplifier 226. In other examples, the amplifier stage 214 may include more or fewer switched cap amplifiers than depicted in the FIG. 2 example. For example, further switched cap amplifiers not depicted in FIG. 2 may be used to receive a detect output signal 257 of the amplifier stage 214 and generate the output signal 244.

In the example of FIG. 2, the switched cap detector 222 is operable to generate a detection signal 253 at the node labeled g_2 in FIG. 2. The switched cap detector 222 is configured to output the detection signal 253 to the first switched cap amplifier 224, which amplifies and/or inverts the detection signal 253 to output an amplified detection signal 255 to the second switched cap amplifier 226 as shown at the node g_3 in FIG. 2. The second switched cap amplifier 226 further amplifies and/or inverts the detection signal 255 to generate the detect output signal 257.

As described, the amplified detection signal 255 may be described as a first amplified detection signal output by the first switched cap amplifier 224, and the detect output signal 257 may be described as a second amplified detection signal output by the second switched cap amplifier 226.

In the example of FIG. 2, the first switched cap amplifier 224 includes a second switch sw_4 coupled across a gate terminal and the drain terminal of a second transistor N2 234. As shown in FIG. 2, the first switched cap amplifier 224 includes a gate terminal coupled (at the node labeled g_2) between a capacitor C3 and a capacitor C4 coupled in series between the drain terminal of the first transistor N1 232 and the drain terminal of the second transistor N2 234. A source terminal of the second transistor N2 234 is coupled to the ground reference GND. In the example of FIG. 2, the amplifier stage 214 further includes a current source 228B that supplies a current I_bias to the first switched cap amplifier 224. In the FIG. 2 example, the current source 228A is configured to supply a current I_bias to a drain terminal of the second transistor N2 234.

In the example of FIG. 2, the second switched cap amplifier 226 includes a third switch sw_4 coupled across a gate terminal and a drain terminal of a third transistor N3 236. As shown in FIG. 2, the second switched cap amplifier 226 includes a gate terminal coupled (at the node labeled g_3) between a capacitor C5 and a capacitor C6 coupled in series between the drain terminal of the second transistor N2 234 and the drain terminal of the third transistor N3 236. A source terminal of the third transistor N3 236 is coupled to the ground reference GND. In the example of FIG. 2, the amplifier stage 214 further includes a current source 228C configured to supply a current to the second switched cap amplifier 226. Specifically, the current source 228C is configured to supply a current to a drain terminal of the third transistor N3 236.

As shown in FIG. 2, a drain terminal of the third transistor N3 236 generates the high frequency (HF) output signal 257, which may be used as an output signal 244 of the detector 201 and/or may be additionally processed to generate the output signal 244. The output signal 244 may be supplied to one or more downstream circuits configured to receive the output signal 244. For example, where the input signal 242 includes a high frequency component, the detector 201 may generate an output signal 244 including one or more pulses. In some examples, downstream circuits, such as wake circuitry (not shown) for a receiver 118 as shown in FIG. 1, may awaken the receiver to receive the input signal 242 responsive to the output signal 244 of the detector 201.

In the example of FIG. 2, the transistors N1 232, N2 234, and N3 236 are shown as metal oxide semiconductor (MOS) transistors. One of ordinary skill in the art will recognize that the detector 201 may also be implemented with other types of transistors, such as any combination of bipolar junction, MOS, or any other type of transistor device. In the example of FIG. 2, the transistors N1 232, N2 234, and N3 236 are shown as n-doped (e.g., n channel transistors). One of ordinary skill in the art will recognize that the detector 201 may also be implemented with one or more p channel transistors with associated circuitry that corresponds to p-doped (e.g., p channel) transistors.

In some examples, one or more of the transistors N1 232, N2 234, and N3 236 of the detector 201 may not be matched to one another i.e., the transistors N1 232, N2 234, and N3 236 are not specifically selected or fabricated to have nearly identical electrical characteristics. In some examples, that transistors N1 232, N2 234, and N3 236 need not be matched to one another may allow for detector 201 to be implemented as relatively low cost, small and/or fast circuit.

In some examples, although not depicted in the FIG. 2 example, the various switches sw_1, sw_2, sw_3, sw_4 and sw_5 may be implemented by one or more switch transistor device structures configured to be controllable by a gate terminal as logic gates/switches to turn on or turn off to allow or inhibit a current to flow across drain and source terminals of the switch transistor. In some examples, one or more of the respective switches sw_1, sw_2, sw_3, sw_4 and sw_5 depicted in FIG. 2 may be implemented as normally off switch transistors configured to allow a current to flow when a voltage is applied to a gate terminal. In other examples, one or more of the respective switches sw_1, sw_2, sw_3, sw_4 and sw_5 depicted in FIG. 2 may be implemented as normally on transistors configured to inhibit a current from flowing when a voltage is applied to the gate terminal of the switch transistor.

In some examples, the current sources 228A-228C may be any circuit or device configured to generate a bias current I_bias with a substantially stable amplitude. In one non-limiting example, a beta multiplier circuit and/or other circuitry may be used the one or more current sources 228A-228C to generate the bias current I_bias. In some examples, one or more of the current source(s) 228A-228C may be adjustable to adapt a sensitivity of the detector 201 to different applications and/or conditions.

In some examples, the respective current sources 228A-228C may supply the same current (i.e., a bias current of the same amplitude), or the respective current sources may apply different currents to the switched cap detector 222, the first switched capacitor amplifier 224, and the second switched cap amplifier 226 respectively. In some examples, the respective current sources 228A-228C are implemented via a single current source circuit (e.g., a single beta multiplier circuit) and one or more current mirror circuits (not shown) that to supply a duplicate bias current I_bias to two or more of the switched cap detector 222, the first switched cap amplifier 224, and the second switched cap amplifier 226.

In some examples, a gain of the respective switched cap detector 222, first switched cap amplifier 224, and second switched cap amplifier 226 are controllable by selecting the respective capacitance rations of the C1/2, C3/C4, C5/C6 capacitors. In some examples, the respective capacitances may be selected such that dependency of detector 201 operation on a gain (i.e., gₘ, g_{ds}) of the transistors N1 232, N2 234, and N3 236 is quite small.

In some examples, the first switched cap amplifier 224 and the second switched cap amplifier 226 are operated on different clocks to amplify a detection signal from the switched cap detector 222. For example, as shown in FIG. 2 the switched cap detector 222 and the first switched cap amplifier 224 may be operated responsive to a first clock signal clk_0, and the second switched cap amplifier 226 may be operated responsive to a second clock signal clk_1 that is different than the first clock signal clk_0. As also shown in FIG. 2, the switches sw_1 and sw_2 may be operated responsive to a third clock signal clk_2.

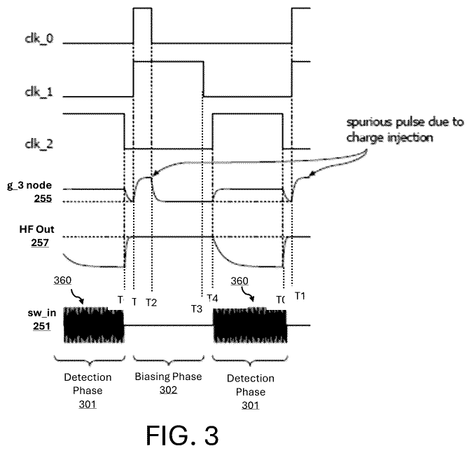

FIG. 3 is a timing diagram showing respective signals associated with operation of a detector such as detector 201 depicted in FIG. 2 according to some embodiments. As shown in FIG. 3, the detector 201 is operated alternately in a detection phase 301 and a biasing phase 302 in accordance with transitions in a clock signal clk_2.

For example, the clock signal clk_2 may be supplied to switches sw_1 and sw_2 shown in the FIG. 2 diagram to alternate between coupling the detector input sw_in 251 to the input signal 242 in the detection phase 301, and coupling the detector input sw_in 251 to a ground reference GND in the biasing phase 302. For example, prior to the time T0, in a detection phase 301 of detector 201, the sw_1 switch is closed and the sw_2 switch is opened such that the input signal 242 is coupled to the detector input sw_in 251 and decoupled from the ground reference GND.

At the time T0, the clock signal clk_2 transitions from high to low and the detector 201 transitions to the biasing phase 302, in which the sw_1 switch is opened to decouple the detector input sw_in 251 from the input signal 242, and the sw_2 switch is closed to couple the detector input sw_in 251 to the ground reference GND.

As shown in FIG. 3, at time T3 the clock signal clk_2 transitions from high to low and the detector 201 transitions back to the detection phase 301, in which the sw_1 switch is closed and the sw_2 switch is opened so that the input signal 242 is coupled to the detector input sw_in 251 and decoupled from the ground reference GND. In operation the detector 201 may transition back and forth between the detection phase 301 and the biasing phase 302 in order to determine the presence of a high frequency component 360 in an input signal 242, e.g., as shown in the detect output signal 257 shown in FIG. 3.

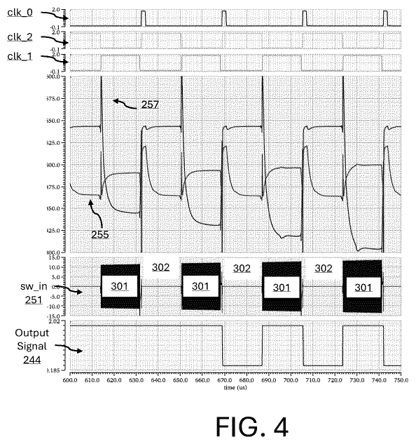

In addition to the clock signal clk_2, FIG. 3 also shows operation of a clock signal clk_0 to control the sw_3 and sw_4 switches of the respective switched cap detector 222 and switched cap amplifier 224, and a clock signal clk_1 that controls the switch sw_5 of the second switched cap amplifier 226 shown in the FIG. 2 example. FIG. 3 also shows an amplified detection signal 255 at the g_3 node which, as shown in FIG. 2, is coupled to the gate terminal of the N3 transistor 236, at a junction between the C5 and C6 capacitors. The amplified detection signal 255 at node g_3 may correspond to an amplified and/or inverted version of the detection signal 253 at the node labeled g_2 in FIG. 2. FIG. 4 also shows the detect output signal 257 at an output of the second switched cap amplifier 226 (at a drain terminal of the third transistor 236).

As shown in FIG. 3, before the time T0, the clock signals clk_0, clk_1 represent a logic low (a low voltage level) meaning that the sw_3 and sw_4 switches are open (e.g., disconnecting the gate and drain terminals of the transistors N1 232 and N2 234), and the clock signal clk_2 transitions from high (a logic high value, corresponding to a high voltage level) to low to decouple the detector input 151 from the input signal 242 to begin the biasing phase 302.

As shown in FIG. 3, at a time T1, shortly after the clock signal clk_2 transitions from high to low, the clock signal clk_0 transitions from low to high, closing the switches sw_3 and sw_4 and, coupling the respective drain and gate terminals of the transistors N1 232 and N2 234 to one another. In some examples, closing the switches sw_3 and sw_4 results in a charge injection that shifts a biasing point of the transistor N1 232 and the transistor N2 234. Also at time T1, the clk_1 signal likewise transitions from low to high, closing the switch sw_5 and coupling the drain terminal of the transistor N3 236 to the source terminal of the transistor N3 236.

As shown in FIG. 3, at a time T2, the clock signal clk_0 transitions from high to low shortly after the time T1 when the clock signal clk_0 transitioned from low to high, opening the switches sw_3 and sw_4 and, decoupling the respective drain and gate terminals of the transistors N1 232 and N2 234 from one another. In some examples, opening the switches sw_3 and sw_4 causes an opposite shift to biasing point of the transistor N1 232 and the transistor N2 234 relative to the previous shift at time T1. In some examples, opening and closing the sw_3 and sw_4 switches causes a spurious pulse to be generated in correspondence with the clock signal clk_0 as shown by the amplified detection signal 255 at the g_3 node.

In some examples, once the spurious pulse has dissipated, biasing points of the switched cap detector 222 and the first switched cap amplifier 224 are settled (i.e., substantially equal, at equilibrium with one another) unless the input signal 242 includes a high frequency component 360 as shown in detection phase 301 in the FIG. 4 timing diagram. In some examples, by biasing the transistor N3 via the clock signal clk_1 controlling the switch sw_5 as shown, when a high frequency component is not present in the input signal 242, the spurious pulse shown in the amplified detection signal 255 at the g_3 node dissipates before the clock signal clk_1 transitions low. In some examples a duration of the respective low to high and high to low transition in the clock signal clk_1 is selected to be long enough for the spurious pulse to dissipate. For example, a period of the clock signal clk_1 may be selected to be substantially longer (i.e., a longer duration between transitions) than a duration of the clock signal clk_0 pulse (i.e., from time T1 to time T2).

As also shown in FIG. 3, at a time T3, the clock signal clk_1 transitions low, a short time before a time T4 when the clk_2 signal transitions from low to high, coupling the detector input sw_in 251 to the input signal 242 to begin a further detection phase 301. As also shown in FIG. 3, at the time T4 when the clock signal clk_2 transitions from low to high, if the input signal 242 includes a high frequency component 360, a pulse is generated in the amplified detection signal 255 at the g_3 node of the second switched cap amplifier 226, which is amplified and inverted as the detect output signal 257 at the drain terminal of the third transistor N3 236. In some examples, the depicted pulse in the detect output signal 257 may be used to generate an output signal 244 of the detector 201. In examples not shown in FIG. 3, if the input signal 242 does not include the high frequency component 360, the depicted pulse is not generated in the amplified detection signal 255 at the g_3 node.

As shown in FIG. 3, a pulse in the amplified detection signal 255 at the g_3 node may be inverted and amplified as the detect output signal 257, which may be used to generate an output signal 244 of the detector 201. In some examples, one or more downstream circuits such as a wake circuit 119 associated with a receiver 118 as shown in FIG. 1 may be configured to monitor the output signal 244, and when the output signal 244 transitions (low or high, depending on the configuration), the wake circuit 119 awakens the receiver 118 to receive (e.g., detect, demodulate, sample and/or otherwise process) the input signal 242. In some examples, the receiver 118 may awaken to receive an input signal 242 in response to detecting a single pulse in the output signal 244. In other examples, the receiver 118 may be awakened after a predetermined number of pulses are detected before awakening to receive the input signal 242.

In some examples, the respective clock signals clk_0, clk_1, and clk_2 depicted FIG. 3 may each have a respective frequency F_{clk} that is relatively low in comparison to a carrier frequency F_{c} of the input signal 242. For example, where the carrier frequency F_{c} of the input signal 142 is greater than 1 megahertz or greater than 10 MHz, the respective frequencies F_{clk} of the respective clock signals clk_0, clk_1, and clk_2 may be less than 100 kilohertz (kHz).

In some examples, the detector 201 depicted in FIG. 2 may be operated according to the respective clock signals clk_0, clk_1, and clk_2 depicted in FIG. 3 to detect whether the input signal 242 includes a high frequency component 360. In some examples, the detector 201 may be periodically operated each time a sleep timer elapses to operate in the respective detection phase 301 and the biasing phase 302 to determine whether the input signal 242 includes the high frequency component 360 and send the output signal 244 in response. In some examples, the detector 201 may advantageously operate with reduced power consumption and/or reduced cost/complexity than traditional detector circuits used to detect a high frequency component in an input signal.

FIG. 4 depicts plots showing simulation results of a detector 201 according to some embodiments. The simulations were run using models built in 28 nanometer (n28) technology. FIG. 4 shows the respective clock signals clk_0, clk_1, and clk_2 operated as described above with respect to FIG. 3 in a biasing phase 302 and a detection phase 301 as shown by the detector input sw_in 251. As shown in FIG. 4, the amplified detection signal 255 at the g_3 node shows a pulse with each detection phase 301, which may represent that the input signal 242 has a frequency component that exceeds a voltage of 24 millivolts peak-to-peak (mVpp). As shown in FIG. 4, the pulses of the amplified detection signal 255 are inverted and amplified as the detect output signal 257. As shown in FIG. 4, after one or morepulses of the detect output signal 257 have an amplitude that exceeds a threshold (e.g., around 430 millivolts (mV) in a non-limiting example), the detector 201 generates an output signal 244 that indicates the input signal 242 includes a high frequency component 360. In the depicted example, the output signal 244 is a squared waveform that includes a series of pulses that correspond to the pulses of the Detect output signal 257 after applying a delay. In some examples, additional circuitry not depicted herein, such as one or more further comparator and/or amplification stages similar to the switched cap detector 222, first switched cap amplifier 224, and/or second switched cap amplifier 226 shown in FIG. 2 may be used to generate the output signal 244 from the Detect output signal 257 as shown in the FIG. 4 example.

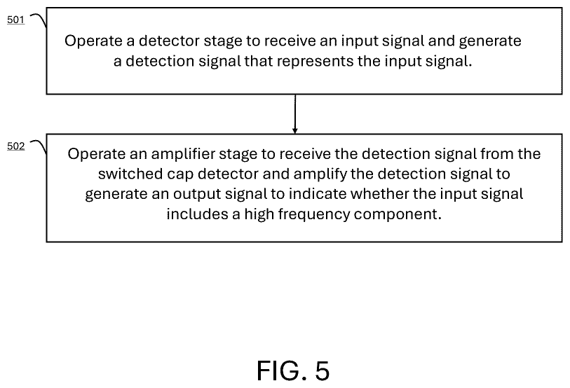

FIG. 5 is a flow diagram that depicts a method of operating a detector 101, 201 according to some embodiments. As shown in FIG. 5, at step 501, the method includes operating a detector stage 112 to receive an input signal 142 and generate a detection signal 153, that represents the input signal 142 (e.g., the presence of a high frequency component in the input signal 142). As shown in FIG. 5, at step 502, the method further includes operating an amplifier stage 114 following the detector stage 112 to receive the detection signal 153, from the detector stage 112 and amplify the detection signal 153, to generate an output signal 144 that indicates whether the input signal 142 includes a high frequency component 360.

In some examples, the detector stage 212 includes a switched cap detector 222 and the amplifier stage 214 includes a first switched cap amplifier 224 and a second switched cap amplifier 226. In some examples, the method further includes operating the switched cap detector 222 and the first switched cap amplifier 224 responsive to a first clock signal clk_0, and operating the second switched cap amplifier 226 responsive to a second clock signal clk_1 different than the first clock signal clk_0.

In some examples, the method further includes operating at least one switch 105, 205 to alternate between a detection phase 301 in which a detector input 151 is coupled to the input signal 142, and a biasing phase 302 in which the detector input 151 is coupled to a ground reference GND. In some examples, operating the switched cap detector 222 and the first switched cap amplifier 224 responsive to the first clock signal clk_0 injects a spurious pulse. In some examples, the method further includes operating the second switched cap amplifier 226 responsive to the second clock signal clk_1 to transition before an end of the biasing phase 302 after the spurious pulse has expired.

In some examples, the method further includes if, at the end of the biasing phase 302, the detection signal 253 represents a high frequency component 360, the second switched cap amplifier 226 amplifies the detection signal 253 and generates an output signal 244 that indicates that the input signal 242 includes the high frequency component 360 (e.g., in the form of a pulse). In some examples, the method further includes if, at the end of the biasing phase 302 the detection signal 253 does not represent a high frequency component 360, the second switched cap amplifier 226 generates an output signal 244 that does not indicate that the input signal 242 includes the high frequency component 360 (e.g., without a pulse).

In some examples, the method further includes operating at least one current source 228A-228C to supply a bias current I_bias to the drain terminals of one or more of a first transistor 232, a second transistor 234, and a third transistor 236. In some examples, the method further includes using a beta multiplier circuit to supply the bias current I_bias.

### Clauses

Clause 1. A detector, comprising: a detector stage configured to receive an input signal and generate a detection signal that represents the input signal; and an amplifier stage that configured to receive the detection signal from the detector stage and amplify the detection signal to generate an output signal that indicates whether the input signal includes a high frequency component.

Clause 2. The detector of clause 1, wherein the detector stage includes a switched cap detector and the amplifier stage includes a first switched cap amplifier and a second switched cap amplifier.

Clause 3. The detector of clause 2, wherein the switched cap detector and the first switched cap amplifier are operated responsive to a first clock signal, and the second switched cap amplifier is operated responsive to a second clock signal different than the first clock signal.

Clause 4. The detector of clause 3, further comprising: at least one switch that alternates between: a detection phase in which a detector input is coupled to the input signal; and a biasing phase in which the detector input is coupled to a ground reference.

Clause 5. The detector of clause 4, wherein the switched cap detector and the first switched cap amplifier inject a spurious pulse when operated responsive to the first clock signal.

Clause 6. The detector of clause 5, wherein the second switched cap amplifier is operated responsive to the second clock signal to transition before an end of the biasing phase after the spurious pulse has expired.

Clause 7. The detector of any of clauses 4-6, wherein if, at an end of the biasing phase the detection signal represents a high frequency component, the second switched cap amplifier amplifies the detection signal and generates an output signal that indicates that the input signal includes the high frequency component.

Clause 8. The detector any of clauses 4-7, wherein if, at an end of the biasing phase the detection signal does not represent a high frequency component, the second switched cap amplifier generates an output signal that indicates that the input signal does not include the high frequency component.

Clause 9. The detector of any of clauses 4-8, wherein the switched cap detector includes: a first switch coupled across a gate terminal and a drain terminal of a first transistor, wherein the gate terminal of the first transistor is coupled to the detector input through a first capacitor, and wherein a resistor and a second capacitor are coupled in series between the gate terminal and the drain terminal of the first transistor. the first switched cap amplifier includes: a second switch coupled across a gate terminal and a drain terminal of a second transistor, wherein the gate terminal of the second transistor is coupled between a third capacitor and a fourth capacitor; and the second switched cap amplifier includes: a third switch coupled across a gate terminal and a drain terminal of a third transistor wherein the gate terminal of the third transistor is coupled between a fifth capacitor and a sixth capacitor.

Clause 10. The detector of clause 9, further comprising: at least one current source coupled to supply a bias current to drain terminals of one or more of the first transistor, the second transistor, and the third transistor.

Clause 11. A method, comprising: operating a detector stage to receive an input signal and generate a detection signal that represents the input signal; and operating an amplifier stage following the detector stage to receive the detection signal from the detector stage and amplify the detection signal to generate an output signal that indicates whether the input signal includes a high frequency component.

Clause 12. The method of clause 11, wherein the detector stage includes a switched cap detector and the amplifier stage includes a first switched cap amplifier and a second switched cap amplifier.

Clause 13. The method of clause 12, further comprising: operating the switched cap detector and the first switched cap amplifier responsive to a first clock signal; and operating the second switched cap amplifier responsive to a second clock signal different than the first clock signal.

Clause 14. The method of clause 13, further comprising: operating at least one switch to alternate between: a detection phase in which a detector input is coupled to the input signal; and a biasing phase in which the detector input is coupled to a ground reference.

Clause 15. The method of clause 14, wherein operating the switched cap detector and the first switched cap amplifier responsive to the first clock signal injects a spurious pulse.

Clause 16. The method of clause 15, further comprising: operating the second switched cap amplifier responsive to the second clock signal to transition before an end of the biasing phase after the spurious pulse has expired.

Clause 17. The method of any of clauses 14-16, wherein if, at an end of the biasing phase the detection signal represents a high frequency component, the second switched cap amplifier amplifies the detection signal and generates an output signal that indicates that the input signal includes the high frequency component.

Clause 18. The method of any of clauses 12-16, further comprising: operating at least one current source to supply a bias current to drain terminals of one or more of the switched cap detector, the first switched cap amplifier, and the second switched cap amplifier.

Clause 19. A system, comprising: a receiver configured to receive an input signal and extract data from the input signal; a detector, comprising: a detector stage configured to receive an input signal and generate a detection signal that represents the input signal; and an amplifier stage configured to receive the detection signal from the detector stage and amplify the detection signal to generate an output signal that indicates whether the input signal includes a high frequency component; and a wake circuit configured to wake the receiver in response to the output signal of the detector.

Clause 20. The system of clause 19, wherein the detector stage includes a switched cap detector and the amplifier stage includes a first switched cap amplifier and a second switched cap amplifier.

Clause 21. The system of any of clauses 19 and 20, wherein the switched cap detector and the first switched cap amplifier are operated responsive to a first clock signal, and the second switched cap amplifier is operated responsive to a second clock signal different than the first clock signal.

Clause 22. The detector of any of clauses 19-21, further comprising: at least one switch that alternates between: a detection phase in which a detector input is coupled to the input signal; and a biasing phase in which the detector input is coupled to a ground reference.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A detector, comprising:
a detector stage configured to receive an input signal and generate a detection signal that represents the input signal; and
an amplifier stage that configured to receive the detection signal from the detector stage and amplify the detection signal to generate an output signal that indicates whether the input signal includes a high frequency component.

2. The detector of claim 1, wherein the detector stage includes a switched cap detector and the amplifier stage includes a first switched cap amplifier and a second switched cap amplifier.

3. The detector of claim 2, wherein the switched cap detector and the first switched cap amplifier are operated responsive to a first clock signal, and the second switched cap amplifier is operated responsive to a second clock signal different than the first clock signal.

4. The detector of claim 3, further comprising:
at least one switch that alternates between:
a detection phase in which a detector input is coupled to the input signal; and
a biasing phase in which the detector input is coupled to a ground reference.

5. The detector of claim 4, wherein the switched cap detector and the first switched cap amplifier inject a spurious pulse when operated responsive to the first clock signal to.

6. The detector of claim 5, wherein the second switched cap amplifier is operated responsive to the second clock signal to transition before an end of the biasing phase after the spurious pulse has expired.

7. The detector of claim 4, wherein if, at an end of the biasing phase the detection signal represents a high frequency component, the second switched cap amplifier amplifies the detection signal and generates an output signal that indicates that the input signal includes the high frequency component.

8. The detector of claim 4, wherein if, at an end of the biasing phase the detection signal does not represent a high frequency component, the second switched cap amplifier generates an output signal that indicates that the input signal does not include the high frequency component.

9. The detector of claim 4, wherein
the switched cap detector includes:
a first switch coupled across a gate terminal and a drain terminal of a first transistor, wherein the gate terminal of the first transistor is coupled to the detector input through a first capacitor, and wherein a resistor and a second capacitor are coupled in series between the gate terminal and the drain terminal of the first transistor;
the first switched cap amplifier includes:
a second switch coupled across a gate terminal and a drain terminal of a second transistor, wherein the gate terminal of the second transistor is coupled between a third capacitor and a fourth capacitor; and
the second switched cap amplifier includes:
a third switch coupled across a gate terminal and a drain terminal of a third transistor wherein the gate terminal of the third transistor is coupled between a fifth capacitor and a sixth capacitor.

10. The detector of claim 9, further comprising:
at least one current source coupled to supply a bias current to drain terminals of one or more of the first transistor, the second transistor, and the third transistor.

11. A method, comprising:
operating a detector stage to receive an input signal and generate a detection signal that represents the input signal; and
operating an amplifier stage following the detector stage to receive the detection signal from the detector stage and amplify the detection signal to generate an output signal that indicates whether the input signal includes a high frequency component.

12. The method of claim 11, wherein the detector stage includes a switched cap detector and the amplifier stage includes a first switched cap amplifier and a second switched cap amplifier.

13. The method of claim 12, further comprising:
operating the switched cap detector and the first switched cap amplifier responsive to a first clock signal; and
operating the second switched cap amplifier responsive to a second clock signal different than the first clock signal.

14. The method of claim 13, further comprising:
operating at least one switch to alternate between:
a detection phase in which a detector input is coupled to the input signal; and
a biasing phase in which the detector input is coupled to a ground reference.

15. The method of claim 14, wherein operating the switched cap detector and the first switched cap amplifier responsive to the first clock signal injects a spurious pulse.

16. The method of claim 15, further comprising:
operating the second switched cap amplifier responsive to the second clock signal to transition before an end of the biasing phase after the spurious pulse has expired.

17. The method of claim 14, wherein if, at an end of the biasing phase the detection signal represents a high frequency component, the second switched cap amplifier amplifies the detection signal and generates an output signal that indicates that the input signal includes the high frequency component.

18. The method of claim 12, further comprising:
operating at least one current source to supply a bias current to drain terminals of one or more of the switched cap detector, the first switched cap amplifier, and the second switched cap amplifier.

19. A system, comprising:
a receiver configured to receive an input signal and extract data from the input signal;
a detector, comprising:
a detector stage configured to receive an input signal and generate a detection signal that represents the input signal; and
an amplifier stage configured to receive the detection signal from the detector stage and amplify the detection signal to generate an output signal that indicates whether the input signal includes a high frequency component; and
a wake circuit configured to wake the receiver in response to the output signal of the detector.

20. The system of claim 19, wherein the detector stage includes a switched cap detector and the amplifier stage includes a first switched cap amplifier and a second switched cap amplifier.

21. The system of claim 20, wherein the switched cap detector and the first switched cap amplifier are operated responsive to a first clock signal, and the second switched cap amplifier is operated responsive to a second clock signal different than the first clock signal.

22. The detector of claim 20, further comprising:
at least one switch that alternates between:
a detection phase in which a detector input is coupled to the input signal; and
a biasing phase in which the detector input is coupled to a ground reference.
